(19) United States
(12) Patent Application Publication
(10) Pub. No.: US 2023/0335419 A1
(43) Pub. Date: Oct. 19, 2023

(54) ETCHING DEVICE AND ETCHING METHOD

(71) Applicant: UNIMICRON TECHNOLOGY CORP., Taoyuan City (TW)

(72) Inventors: Chin-Sheng Wang, Taoyuan City (TW); Chia-Yu Peng, Taoyuan City (TW); KAI-MING YANG, Taoyuan City (TW); PU-JU LIN, Taoyuan City (TW); CHENG-TA KO, Taoyuan City (TW)

(21) Appl. No.: 17/741,787

(22) Filed: May 11, 2022

(30) Foreign Application Priority Data
Apr. 14, 2022 (TW) 111114312

(51) Int. Cl. C09K 13/04; C23F 1/18

(52) U.S. Cl. CPC C09K 13/04; C23F 1/18

(57) ABSTRACT

The present invention provides an etching device which comprises an oxygen supplier, so that the etching device of the present invention can etch copper gently by means of the dissolved oxygen in the etching solution to accurately control the etching degree so as to fulfill the stricter requirements of microcircuit manufacturing. The present invention further provides an etching method. Finally, the etching waste solution of the present invention can be recycled to further ameliorate the environmental pollution and reduce the production cost, so the present invention is widely applicable in integrated circuit packaging.

### CROSS-REFERENCE TO RELATED APPLICATION

Pursuant to 35 U.S.C. § 119(a), this application claims the benefits of the priority to Taiwan Patent Application No. 111114312, filed on Apr. 14, 2022, which is incorporated by reference herein in its entirety.

### BACKGROUND OF THE INVENTION

### 1. Field of the Invention

The present invention relates to an etching device, especially an etching device and an etching method for copper.

### 2. Description of the Prior Arts

To meet the consumer demand, the miniaturization of electronic products has become a common trend. Therefore, continuous improvement of the manufacturing technology for circuit boards or carrier boards is required, so that the miniaturized circuits in the circuit boards or carrier boards can still demonstrate excellent electrical conductivity. Further, the reliability of the integrated circuits can be improved by taking advantages of the better anti-electromigration capability of copper.

In the current method of forming a circuit on a circuit board or a carrier board, the trace width is generally more than 10 microns with a limit of 2 microns, and is usually prepared by an etching process, wherein chemical etching or chemical corrosion is relatively common. For mounting copper miniature circuits, the composition of etching solution for copper is currently divided into two major systems: (1) sulfuric acid/hydrogen peroxide; and (2) sodium persulfate (SPS). However, these two compositions result in the problems of both high pollution and high cost. Further, the high etching capacity thereof may incur disconnection easily when forming miniature circuits by etching, which poses great difficulties in meeting the process requirements of the next generation of microcircuit: the trace width less than or equal to 1 micron. Therefore, there is necessity to develop a new alternative approach to achieve the goal of miniaturization continuously.

### SUMMARY OF THE INVENTION

To reach the aforementioned object, the present invention provides an etching device, comprising: a carrier supplier, an oxygen supplier, an acid source supplier, a buffer zone, an etching solution supplier and a communicating pipe assembly; wherein the carrier supplier is used for supplying a carrier to the communicating pipe assembly; the oxygen supplier is used for supplying oxygen to the buffer zone; the acid source supplier is used for supplying an acidic solution to the buffer zone; the buffer zone is used for mixing the carrier, the oxygen and the acidic solution to obtain an etching solution; the etching solution supplier comprises an etching reaction chamber and an etching solution supply unit, and the etching solution supply unit is used for supplying the etching solution to the etching reaction chamber; and the communicating pipe assembly is in fluid communication with the carrier supplier, the buffer zone and the etching solution supplier, sequentially.

The etching device of the present invention, which is disposed with an oxygen supplier and a buffer zone, produces an etching solution with the dissolved oxygen. Therefore, the chemical reaction in the present invention to etch copper by means of the dissolved oxygen in an acidic environment is more gentle than those resulting from the etching solutions of the commonly used series of sulfuric acid/hydrogen peroxide or sodium persulfate, so as to accurately control the etching degree on the targets and make the etched targets obtained by using the etching device of the present invention fulfill the specification requirements: the trace width less than or equal to 1 micron, or even an etching thickness less than or equal to 1 micron for the seed layer in semi-additive process (SAP). Besides, the present invention adopts oxygen to replace the chemicals used in the traditional chemical etching process, which can ameliorate environmental pollution and reduce production cost, so the etching device of the present invention is widely applicable for forming circuits in circuit boards or laminate substrates, such as: printed circuit board (PCB), printed wire board (PWB) or copper-clad laminate (CCL).

The aforementioned circuit board or carrier board is used for carrying and connecting different components, such as: chips, capacitors, etc., so the present invention is used for integrated circuit packaging, and is different from the fields of manufacturing process for the semiconductor chip or other components. Besides, the composition and structure of a chip are significantly different from those of a circuit board or a laminate substrate. As the targets of the chip manufacturing process and the integrated circuit packaging are different, the chip manufacturing process and the integrated circuit packaging lack comparable basis.

In one embodiment, the carrier supplier comprises a switch device, and the switch device can control the delivery of the carrier into the communicating pipe assembly.

In one embodiment, the buffer zone comprises a dissolved oxygen buffer tank and a pH adjustment tank, and the dissolved oxygen buffer tank is in fluid communication with the pH adjustment tank through the communicating pipe assembly; wherein the dissolved oxygen buffer tank connects to the communicating pipe assembly and the oxygen supplier, so that the carrier and the oxygen are mixed in the dissolved oxygen buffer tank; and the pH adjustment tank connects to the communicating pipe assembly and the acid source supplier, so that the carrier and the acidic solution are mixed in the pH adjustment tank.

The purpose to set up the acid source supplier and the pH adjustment tank in the present invention is to control the pH of the etching solution more accurately, so as to further control the influence of the dissolved oxygen on the copper etching rate to increase etching accuracy.

In one embodiment, the etching solution supply unit comprises a spray assembly, so as to evenly sprinkle the etching solution on the surface of the target for chemical etching.

In one embodiment, the etching solution supply unit comprises a switch device for controlling the discharge of the etching solution. The chemical etching is carried out by immersing the target in the etching solution, or by the direct contact between the target and the etching solution.

In one embodiment, the oxygen supplier comprises a pressurizer. Preferably, the pressurizer is a pressurized oxygen delivery device. More preferably, the pressurizer is an oxygen pressure blower.

In one embodiment, the communicating pipe assembly comprises a plurality of communicating pipes, and the communicating pipes connect to each other directly or indirectly. Specifically, the communicating pipes are each in fluid communication with other components of the etching device, such as: the carrier supplier, the buffer zone, the etching solution supplier etc., and then the communicating pipes connect to each other indirectly and are in fluid communication with each other eventually.

In one embodiment, the communicating pipe assembly connects to the carrier supplier, the dissolved oxygen buffer tank, the pH adjustment tank and the etching solution supplier, sequentially. In the present invention, the carrier supplier firstly supplies the carrier to the communicating pipe assembly, and the carrier further enters the dissolved oxygen buffer tank so as to be mixed with the oxygen to obtain a carrier with the dissolved oxygen. The carrier with the dissolved oxygen is then delivered to the pH adjustment tank through the communicating pipe assembly so as to be mixed with the acidic solution to obtain a carrier with the dissolved oxygen and pH<7, which is the etching solution. Finally, the etching solution is delivered to the etching solution supplier through the communicating pipe assembly, and then the etching solution is supplied to the etching reaction chamber by the etching solution supply unit for chemical etching.

In one embodiment, the communicating pipe assembly connects the carrier supplier, the pH adjustment tank, the dissolved oxygen buffer tank and the etching solution supplier, sequentially. In the present invention, the carrier supplier firstly supplies the carrier to the communicating pipe assembly, and the carrier further enters the pH adjustment tank so as to be mixed with the acidic solution to obtain a carrier with pH<7. The carrier with pH<7 is then delivered to the dissolved oxygen buffer tank through the communicating pipe assembly so as to be mixed with oxygen to obtain a carrier with the dissolved oxygen and pH<7, which is the etching solution. Finally, the etching solution is delivered to the etching solution supplier through the communicating pipe assembly, and then the etching solution is supplied to the etching reaction chamber by the etching solution supply unit for chemical etching.

In one embodiment, the present invention further comprises a temperature control assembly connecting to the buffer zone, the communicating pipe assembly or a combination thereof. Preferably, the temperature control assembly connects to the dissolved oxygen buffer tank, the communicating pipe assembly or a combination thereof. More preferably, the temperature control assembly comprises a cooling element and/or a heating element. In the present invention, the temperature control assembly is disposed for further controlling the quantity of the dissolved oxygen to increase etching accuracy.

In one embodiment, the present invention further comprises a circulatory component for recycling, and the circulatory component for recycling comprises an outlet tube, and the outlet tube connects to the etching reaction chamber to drain the etching waste solution. Preferably, the circulatory component for recycling further comprises a recycling tank; wherein the recycling tank connects to the outlet tube, and the recycling tank comprises an electroplating device, so that the metal ions derived from chemical etching can be reduced to metals. The present invention recycles the etching waste solution and the metal ions thereof, thereby ameliorating environmental pollution problems.

In one embodiment, the circulatory component for recycling of the present invention further comprises a heater. Preferably, the heater is a distillatory for separating the carrier from the etching waste solution.

In one embodiment, the recycling tank connects to the carrier supplier. In other words, the carrier or acidic carrier recycled from the etching waste solution in the present invention is reusable, which can lower the production costs and accords with the trend of sustainable development. Preferably, the carrier supplier comprises a switch device for controlling the delivery of the carrier recycled from the etching waste solution to the communicating pipe assembly. That is, the circulatory component for recycling connects the carrier supplier and the etching reaction chamber to form a circulation loop within the etching device of the present invention.

The present invention further provides an etching method, comprising: Step 1: providing an etching solution; wherein the etching solution comprises a carrier, an acidic solution and oxygen; and Step 2: supplying the etching solution to a target placed in an etching reaction chamber for etching the target to obtain an etched target and an etching waste solution; wherein the target comprises a metal, and the etching waste solution comprises a metal ion derived from etching the target.

In one embodiment, the carrier comprises water. Preferably, the water is deionized water.

In one embodiment, the acidic solution comprises one selected from sulfuric acid, nitric acid, hydrochloric acid, hypochlorous acid or a combination thereof. Preferably, the pH of the acidic solution is from 1.5 to less than 7, such as: 1.7, 2, 3, 4, 5, 6, 6.5 or 6.9, but is not limited thereto.

In one embodiment, the carrier is the carrier recycled from the etching waste solution, which comprises the water.

In one embodiment, the carrier is the acidic carrier recycled from the etching waste solution, which comprises a mixture of the water and the acidic solution, or comprises a mixture of the water, the oxygen and the acidic solution.

In one embodiment, the metal is copper.

In one embodiment, the metal ion is copper ions.

In one embodiment, the oxygen is the dissolved oxygen dissolved in the water. In the present invention, copper is etched by the dissolved oxygen in the deionized water in an environment with pH<7, not by hydrogen peroxide.

The present invention further provides an etching system, comprising the etching device, the carrier, the oxygen and the acidic solution. The carrier, the oxygen and the acidic solution are mixed in the etching device to obtain the etching solution.

To sum up, the etching device of the present invention can etch copper gently by means of the dissolved oxygen in the etching solution to accurately control the etching degree so as to fulfill the stricter requirements of microcircuit manufacturing. Besides, the etching waste solution can be recycled to further ameliorate the environmental pollution and reduce the production cost, so the present invention is widely applicable in integrated circuit packaging.

### BRIEF DESCRIPTION OF THE DRAWINGS

FIG. 1 is a schematic diagram of an embodiment of an etching device of the present invention.

FIG. 2 is a schematic diagram of an embodiment of an etching device of the present invention.

FIG. 3 is a schematic diagram of an embodiment of an etching device of the present invention.

FIG. 4 is a schematic diagram of an embodiment of an etching device of the present invention.

FIG. 5 is a schematic diagram of an embodiment of an etching device of the present invention.

FIG. 6 is a schematic diagram of an embodiment of an etching device of the present invention.

### DETAILED DESCRIPTION OF THE PREFERRED EMBODIMENTS

The present invention is further explained through the following embodiments. A person having ordinary skill in the art can easily understand the advantages and efficacies achieved by the present invention. The present invention should not be limited to the contents of the embodiments. A person having ordinary skill in the art can make some improvement or modifications which are not departing from the spirit and scope of the present invention to practice or apply the content of the present invention.

### Example 1: The Etching Device

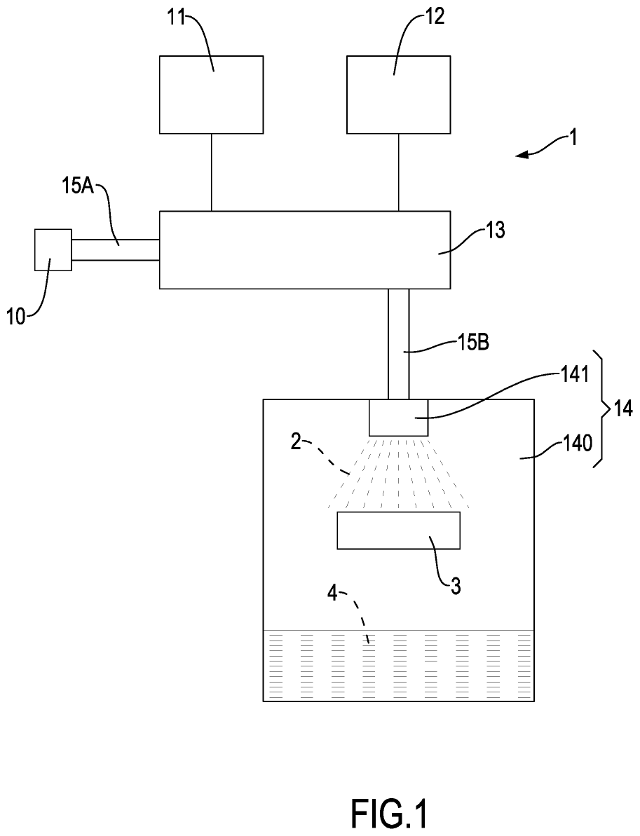

As shown in FIG. 1, the etching device 1 of the present invention comprises: a carrier supplier 10, an oxygen supplier 11, an acid source supplier 12, a buffer zone 13, an etching solution supplier 14 and a segmented communicating pipe assembly 15A, 15B, and the communicating pipe assembly 15A, 15B is in fluid communication with the carrier supplier 10, the buffer zone 13 and the etching solution supplier 14, sequentially; and the etching solution supplier 14 comprises an etching reaction chamber 140 and an etching solution supply unit 141.

The carrier supplier 10 is used for supplying the carrier (not shown) to the communicating pipe assembly 15A; the oxygen supplier 11 is used for supplying oxygen (not shown) to the buffer zone 13; the acid source supplier 12 is used for supplying the acidic solution (not shown) to the buffer zone 13; the buffer zone 13 is used for mixing the carrier, the oxygen and the acidic solution to obtain an etching solution 2; the etching solution 2 enters the etching solution supplier 14 by the communicating pipe assembly 15B, and the etching solution 2 is supplied to the etching reaction chamber 140 by the etching solution supply unit 141 of the etching solution supplier 14.

The oxygen supplier 11 comprises an oxygen pressure blower, which can increase the quantity of the dissolved oxygen. The etching solution supply unit 141 comprises a spray assembly, which can evenly sprinkle the etching solution 2 on the surface of the target 3 for chemical etching.

The etching device 1 of the present invention supplies the etching solution 2 through the etching solution supply unit 141 to the target 3 placed in an etching reaction chamber 140 for etching the target 3 to obtain an etched target and an etching waste solution 4; wherein the target 3 comprises copper, and the etching waste solution 4 comprises copper ions. Further, the etching device 1 of this Example does not comprise the carrier, the oxygen, the acidic solution, the etching solution 2, the target 3 and the etching waste solution 4.

### Example 2: The Etching Device

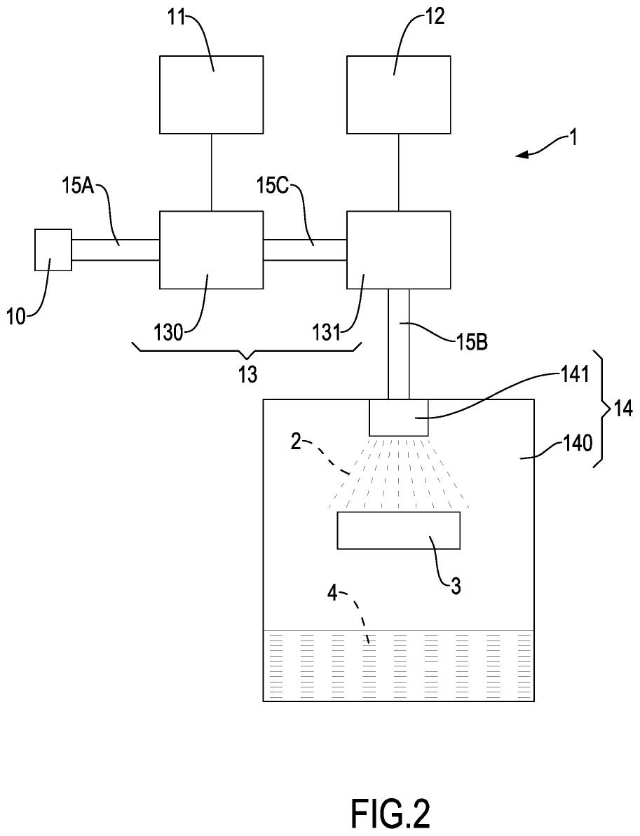

As shown in FIG. 2, the etching device 1 in Example 2 is similar to that in Example 1, and the major difference is the buffer zone 13 in Example 2 comprises a dissolved oxygen buffer tank 130 and a pH adjustment tank 131, which are disposed individually and separated from each other. The dissolved oxygen buffer tank 130 is in fluid communication with the pH adjustment tank through the communicating pipe assembly 15B. The oxygen supplier 11 connects to the dissolved oxygen buffer tank 130, and supplies oxygen (not shown) to the dissolved oxygen buffer tank 130. The acid source supplier 12 connects to the pH adjustment tank 131, and supplies the acidic solution (not shown) to the pH adjustment tank 131.

The dissolved oxygen buffer tank 130 connects to the communicating pipe assembly 15A and the oxygen supplier 11, so that the carrier (not shown) and the oxygen are mixed in the dissolved oxygen buffer tank 130. The pH adjustment tank 131 connects to the communicating pipe assembly 15C and the acid source supplier 12, so that the carrier and the acidic solution are mixed in the pH adjustment tank 131.

The communicating pipe assembly 15A, 15C, 15B connects the carrier supplier 10, the dissolved oxygen buffer tank 130, the pH adjustment tank 131 and the etching solution supplier 14, sequentially. In other words, in the etching device 1 of the present invention, the communicating pipe assembly 15A firstly is in fluid communication with the dissolved oxygen buffer tank 130. The carrier supplier 10 firstly supplies the carrier to the communicating pipe assembly 15A, and the carrier further enters the dissolved oxygen buffer tank 130 so as to be mixed with the oxygen to obtain a carrier with the dissolved oxygen. The carrier with the dissolved oxygen is then delivered to the pH adjustment tank 131 through the communicating pipe assembly 15C so as to be mixed with the acidic solution to obtain a carrier with the dissolved oxygen and pH<7, which is the etching solution 2. Finally, the etching solution 2 is delivered to the etching solution supplier 14 through the communicating pipe assembly 15B, and then the etching solution 2 is supplied to the target 3 placed in the etching reaction chamber 140 by the etching solution supply unit 141 for etching the target 3 to obtain an etched target and an etching waste solution 4.

### Example 3: The Etching Device

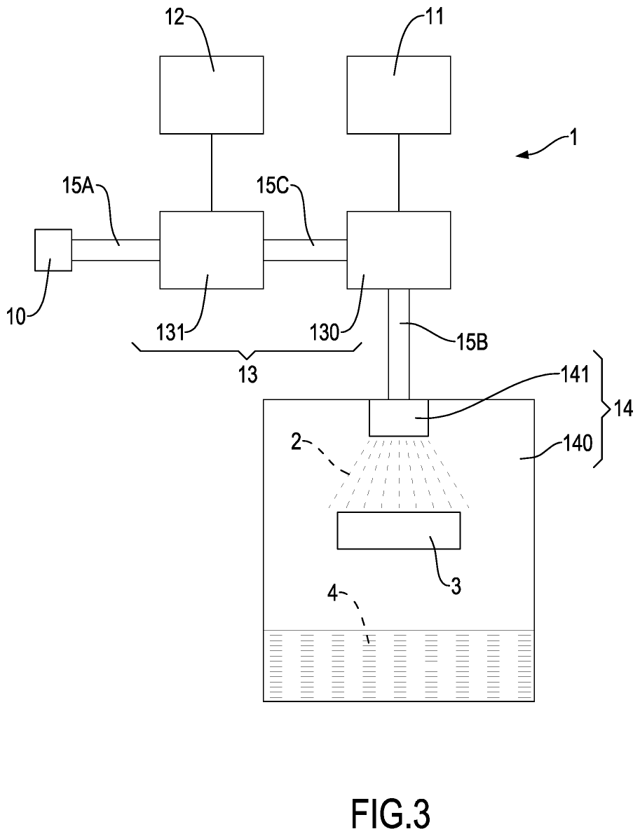

As shown in FIG. 3, the etching device 1 in Example 3 is similar to that in Example 2, and the major difference is that the dissolved oxygen buffer tank 130 and the pH adjustment tank 131 of the buffer zone 13 in Example 3 are disposed in a different order. The communicating pipe assembly 15A, 15C, 15B connects to the carrier supplier 10, the pH adjustment tank 131, the dissolved oxygen buffer tank 130 and the etching solution supplier 14 in sequence.

In other words, the order of adjusting quantity of the dissolved oxygen and pH can be switched. That is, in the etching device 1 of the present invention, the communicating pipe assembly 15A firstly is in fluid communication with the pH adjustment tank 131. The carrier supplier 10 firstly supplies the carrier (not shown) to the communicating pipe assembly 15A, and the carrier further enters the pH adjustment tank 131 so as to be mixed with the acidic solution (not shown) to obtain a carrier with pH<7. The carrier with pH <7 is then delivered to the dissolved oxygen buffer tank 130 through the communicating pipe assembly 15C so as to be mixed with the oxygen to obtain a carrier with the dissolved oxygen and pH<7, which is the etching solution 2. Finally, the etching solution 2 is delivered to the etching solution supplier 14 through the communicating pipe assembly 15B, and then the etching solution 2 is supplied to the etching reaction chamber 140 by the etching solution supply unit 141 for etching the target 3 to obtain an etched target and an etching waste solution 4.

### Example 4: The Etching Device

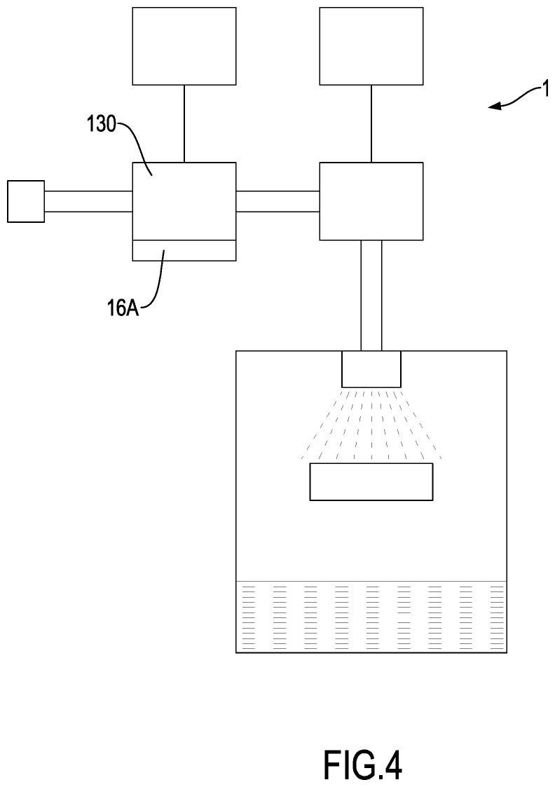

As shown in FIG. 4, the etching device 1 of the present invention is that in Example 2, which further comprises a temperature control assembly 16A. The temperature control assembly 16A connects to the dissolved oxygen buffer tank 130, and can further control the quantity of the dissolved oxygen in the carrier to further increase etching accuracy when using the obtained etching solution.

### Example 5: The Etching Device

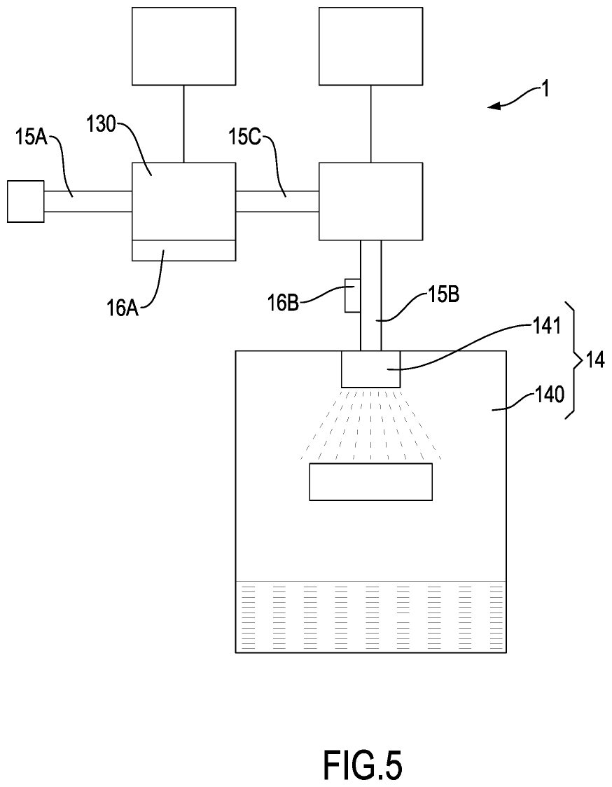

As shown in FIG. 5, the etching device 1 of the present invention comprises the communicating pipe assembly 15A, 15C, 15B. Besides, the etching device 1 of the present invention is that in Example 2, which further comprises the temperature control assembly 16A, 16B. The temperature control assembly 16A, 16B connects to the dissolved oxygen buffer tank 130 and the communicating pipe assembly 15B, respectively. The temperature control assembly 16B is disposed near the site of the etching solution supplier 14, which is the etching reaction chamber 140 or the etching solution supply unit 141, and can further control the quantity of the dissolved oxygen in the carrier to further increase etching accuracy when using the obtained etching solution.

### Example 6: The Etching Device

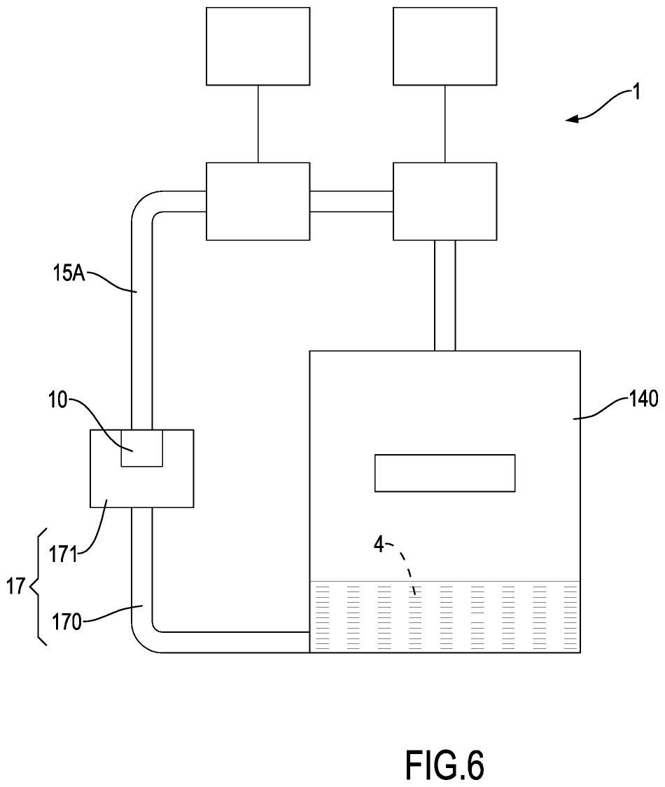

As shown in FIG. 6, the etching device 1 of the present invention further comprises a circulatory component for recycling 17. The circulatory component for recycling 17 comprises an outlet tube 170. The outlet tube 170 connects to the etching reaction chamber 140 to drain the etching waste solution 4.

The circulatory component for recycling 17 further comprises a recycling tank 171. The recycling tank 171 connects to the outlet tube 170. The recycling tank 171 comprises an electroplating device (not shown), which can reduce the metal ions derived from chemical etching to metals to lower the concentration of copper ions in the etching waste solution 4. Besides, the carrier supplier 10 comprises a switch device to control the delivery of the acidic carrier recycled from the etching waste solution 4 to the communicating pipe assembly 15A. Thus, the acidic carrier recycled from the etching waste solution 4 is reusable, which facilitates reducing the production costs and ameliorating environmental pollution. The recycling tank 171 can comprise a heater (not shown), such as: a distillatory for separating the carrier from the etching waste solution 4 to further obtain a purified carrier.

To sum up, the etching device of the present invention can etch copper gently by means of the dissolved oxygen in the etching solution to accurately control the etching degree so as to fulfill the stricter requirements of microcircuit manufacturing. Besides, the etching waste solution of the present invention can be recycled, which further ameliorates the environmental pollution and reduces the production cost, so the present invention is widely applicable in integrated circuit packaging.

What is claimed is:

1. An etching device, comprising:
a carrier supplier, an oxygen supplier, an acid source supplier, a buffer zone, an etching solution supplier and a communicating pipe assembly; wherein
the carrier supplier is used for supplying a carrier to the communicating pipe assembly;
the oxygen supplier is used for supplying oxygen to the buffer zone;
the acid source supplier is used for supplying an acidic solution to the buffer zone;
the buffer zone is used for mixing the carrier, the oxygen and the acidic solution to obtain an etching solution;
the etching solution supplier comprises an etching reaction chamber and an etching solution supply unit, and the etching solution supply unit is used for supplying the etching solution to the etching reaction chamber; and
the communicating pipe assembly is in fluid communication with the carrier supplier, the buffer zone and the etching solution supplier, sequentially.

2. The etching device as claimed in claim 1, wherein the etching solution supply unit comprises a spray assembly or a switch assembly.

3. The etching device as claimed in claim 1, wherein the oxygen supplier comprises a pressurizer.

4. The etching device as claimed in claim 1, wherein the buffer zone comprises a dissolved oxygen buffer tank and a pH adjustment tank, and the dissolved oxygen buffer tank is in fluid communication with the pH adjustment tank through the communicating pipe assembly; wherein the dissolved oxygen buffer tank connects to the communicating pipe assembly and the oxygen supplier, so that the carrier and the oxygen are mixed in the dissolved oxygen buffer tank; and the pH adjustment tank connects to the communicating pipe assembly and the acid source supplier, so that the carrier and the acidic solution are mixed in the pH adjustment tank.

5. The etching device as claimed in claim 4, further comprising a temperature control assembly connecting to the dissolved oxygen buffer tank, the communicating pipe assembly or a combination thereof.

6. The etching device as claimed in claim 1, wherein the etching device further comprises a circulatory component for recycling, and the circulatory component for recycling comprises an outlet tube, and the outlet tube connects to the etching reaction chamber to drain the etching waste solution.

7. The etching device as claimed in claim 2, wherein the etching device further comprises a circulatory component for recycling, and the circulatory component for recycling comprises an outlet tube, and the outlet tube connects to the etching reaction chamber to drain the etching waste solution.

8. The etching device as claimed in claim 3, wherein the etching device further comprises a circulatory component for recycling, and the circulatory component for recycling comprises an outlet tube, and the outlet tube connects to the etching reaction chamber to drain the etching waste solution.

9. The etching device as claimed in claim 4, wherein the etching device further comprises a circulatory component for recycling, and the circulatory component for recycling comprises an outlet tube, and the outlet tube connects to the etching reaction chamber to drain the etching waste solution.

10. The etching device as claimed in claim 5, wherein the etching device further comprises a circulatory component for recycling, and the circulatory component for recycling comprises an outlet tube, and the outlet tube connects to the etching reaction chamber to drain the etching waste solution.

11. The etching device as claimed in claim 6, wherein the circulatory component for recycling further comprises a recycling tank; wherein the recycling tank connects to the outlet tube, and the recycling tank comprises an electroplating device.

12. The etching device as claimed in claim 7, wherein the circulatory component for recycling further comprises a recycling tank; wherein the recycling tank connects to the outlet tube, and the recycling tank comprises an electroplating device.

13. The etching device as claimed in claim 8, wherein the circulatory component for recycling further comprises a recycling tank; wherein the recycling tank connects to the outlet tube, and the recycling tank comprises an electroplating device.

14. The etching device as claimed in claim 9, wherein the circulatory component for recycling further comprises a recycling tank; wherein the recycling tank connects to the outlet tube, and the recycling tank comprises an electroplating device.

15. The etching device as claimed in claim 10, wherein the circulatory component for recycling further comprises a recycling tank; wherein the recycling tank connects to the outlet tube, and the recycling tank comprises an electroplating device.

16. The etching device as claimed in claim 11, wherein the recycling tank connects to the carrier supplier.

17. The etching device as claimed in claim 12, wherein the recycling tank connects to the carrier supplier.

18. The etching device as claimed in claim 13, wherein the recycling tank connects to the carrier supplier.

19. The etching device as claimed in claim 14, wherein the recycling tank connects to the carrier supplier.

20. The etching device as claimed in claim 15, wherein the recycling tank connects to the carrier supplier.

21. An etching method, comprising:
Step 1: providing an etching solution; wherein the etching solution comprises a carrier, an acidic solution and oxygen; and
Step 2: supplying the etching solution to a target placed in an etching reaction chamber for etching the target to obtain an etched target and an etching waste solution; wherein the target comprises a metal, and the etching waste solution comprises a metal ion derived from etching the target.

22. The etching method as claimed in claim 21, wherein the metal is copper, the carrier is water, and the oxygen is dissolved oxygen dissolved in the water.
